(19) United States
(12) Patent Application Publication
(10) Pub. No.: US 2005/0282320 A1
(43) Pub. Date: Dec. 22, 2005

(54) Method of manufacturing semiconductor device

(75) Inventor: Atsushi Hasuike, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/986,225

(22) Filed: Nov. 12, 2004

(30) Foreign Application Priority Data
Jun. 22, 2004 (JP) 2004-183848

(51) Int. Cl. H01L 21/338

(52) U.S. Cl. 438/167; 438/182

(57) ABSTRACT

A method of manufacturing a semiconductor device includes forming a gate electrode on a semiconductor substrate, forming a resist on the semiconductor substrate so that the resist contacts only one side face of the gate electrode, and tilting the gate electrode by shrinking or expanding the resist.

### BACKGROUND OF THE INVENTION

1. Field of the Invention

The present invention relates to a method of manufacturing a semiconductor device capable of realizing a high-frequency semiconductor.

2. Background Art

In order to realize a high-frequency semiconductor device, it is the most effective means that a gate length is shortened and a cutoff frequency is raised. However, in the current EB (electron beam) exposure technique, there is a limit to shorten a gate length, and it is difficult to manufacture a gate electrode having a gate length being about 0.1 μm long.

Therefore, in the conventional MESFET (Metal Semiconductor Field Effect Transistor) and HEMT (High Electron Mobility Transistor), it has been difficult to obtain a high frequency over 100 GHz.

Meanwhile, a method, wherein a gate length is shortened by diagonally forming a gate electrode is suggested (for example, refer to Japanese Unexamined Patent Application Publication No. H05-129343, Japanese Unexamined Patent Application Publication No. H11-111733, and Japanese Unexamined Patent Application Publication No. H05-144847).

However, in the conventional methods of manufacturing a semiconductor device, there is a problem that a step of manufacturing a semiconductor device becomes complicated since a gate electrode is diagonally formed.

### SUMMARY OF THE INVENTION

The invention is intended to resolve the foregoing problems. It is an object of the invention to obtain a method of manufacturing a semiconductor device capable of shortening a gate length by diagonally tilting a gate electrode by a simple method.

According to one aspect of the present invention, a method of manufacturing a semiconductor device includes the step of forming a gate electrode on a semiconductor substrate, the step of forming a resist on the semiconductor substrate so that the resist contacts only one side face of the gate electrode, and the step of tilting the gate electrode by shrinking or expanding the resist.

According to the invention, it is possible to shorten a gate length by diagonally tilting a gate electrode by a simple method. Further, along with the foregoing, a cutoff frequency can be raised, and a high-frequency semiconductor can be realized.

Other and further objects, features and advantages of the invention will appear more fully from the following description.

### BRIEF DESCRIPTION OF THE DRAWINGS

FIGS. 1A-1D, 2A and 2B show a method of forming a gate electrode in a first embodiment.

FIG. 3 shows the gate electrode is tilted by shrinking the resist in a first embodiment.

FIG. 4 shows the gate electrode is tilted by expanding the resist in a first embodiment.

FIG. 5 shows a gate electrode having a T-shape cross section is used in a second embodiment.

FIG. 6 shows a gate electrode having a Y-shape cross section is used in a second embodiment.

FIG. 7 shows a method of manufacturing a semiconductor device according to a third embodiment of the invention.

FIG. 8 shows a method of manufacturing a semiconductor device according to a fourth embodiment of the invention.

FIG. 9 shows a method of manufacturing a semiconductor device according to a fifth embodiment of the invention.

FIG. 10 shows the gate electrode is tilted by expanding the resist in a sixth embodiment.

FIG. 11 shows the gate electrode is tilted by shrinking the resist in a sixth embodiment.

FIG. 12 shows a method of manufacturing a semiconductor device according to a seventh embodiment of the invention.

### DETAILED DESCRIPTION OF THE PREFERRED EMBODIMENTS

### First Embodiment

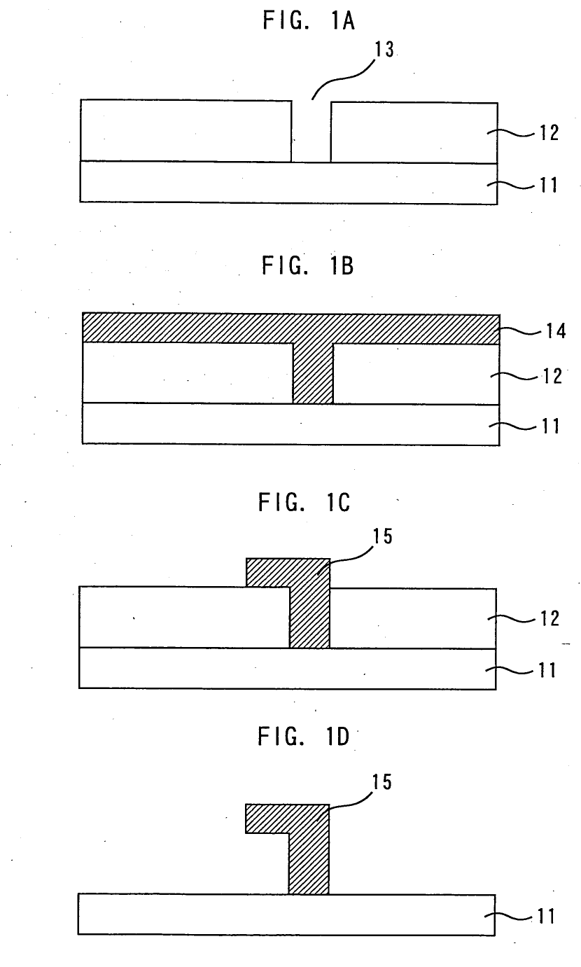

Descriptions will be hereinafter given of a method of manufacturing a semiconductor device according to a first embodiment of the invention with reference to FIGS. 1A-1D, 2A, 2B, 3 and 4.

First, as shown in FIG. 1A, an insulating film 12 made of SiN or the like is formed on a semiconductor substrate 11 made of GaAs or the like. Then, an opening 13 is formed in the insulating film 12 by EB or photolithography.

Next, as shown in FIG. 1B, a metal film 14 made of Al or the like is formed on a whole area to infill the opening 13. Then, as shown in FIG. 1C, the metal film 14 is provided with patterning by photo lithography to form a gate electrode 15 having a Γ-shape cross section. After that, as shown in FIG. 1D, the insulating film 12 is removed. By the foregoing steps, the gate electrode is formed on the semiconductor substrate.

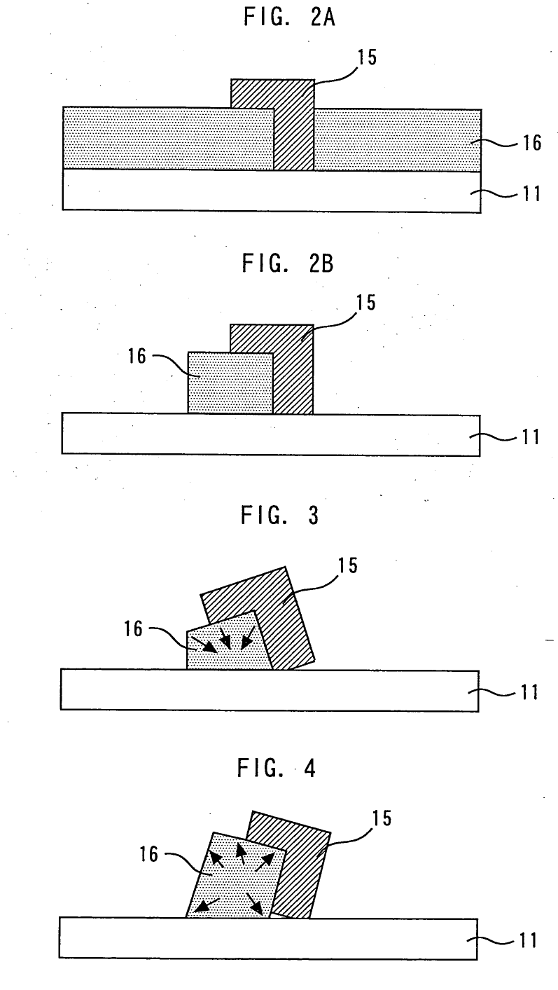

Next, as shown in FIG. 2A, a resist 16 is formed on a whole area of the semiconductor substrate 11. Then, as shown in FIG. 2B, by exposure and development steps, the resist 16 is removed except for a part thereof contacting one side face of the gate electrode 15. By the foregoing steps, the resist is formed on the semiconductor substrate so that the resist only contacts one side face of the gate electrode. However, as the resist 16, a material which is shrunk or expanded by heat treatment or chemical treatment.

Next, the gate electrode 15 is tilted by shrinking the resist 16 as shown in FIG. 3 or by expanding the resist 16 as shown in FIG. 4 by heat treatment or chemical treatment.

As described above, a gate length can be shortened by diagonally tilting the gate electrode by the simple method. Further, along with the foregoing, a cutoff frequency can be raised, and a high-frequency semiconductor device can be realized.

In the foregoing first embodiment, descriptions have been given of the case wherein a cross section shape of the gate electrode is Γ. However, a cross section shape of the gate electrode is not limited to the foregoing shape. An ordinary rectangle shape can provide similar effects. However, it is more effective when the cross section shape of the gate electrode is Γ, since the resist gets in below the gate electrode, and therefore, shrinkage or expansion force is easily applied.

### Second Embodiment

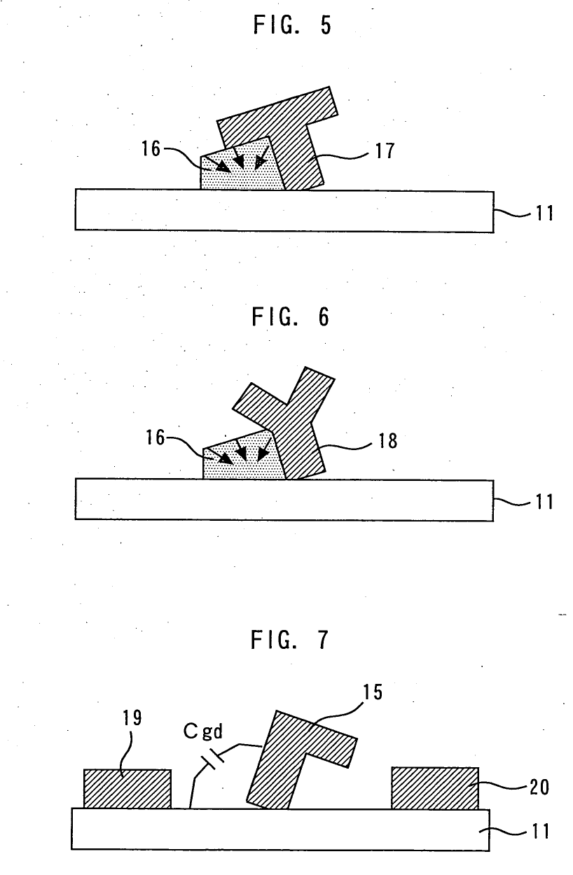

In the first embodiment, the cross section shape of the gate electrode is Γ. Meanwhile, in a second embodiment, a gate electrode 17 having a T-shape cross section as shown in FIG. 5 is used, or a gate electrode 18 having a Y-shape cross section as shown in FIG. 6 is used. In the case that a cross section of the gate electrode is T shape or Y shape as above, the resist gets in below the gate electrode, and shrinkage or expansion force is easily applied similarly to in the case of Γ shape in the first embodiment. Therefore, in the second embodiment, effects similar to in the first embodiment can be obtained.

### Third Embodiment

In the third embodiment, a drain electrode 19 and a source electrode 20 are provided on the semiconductor substrate 11, and the gate electrode 15 is tilted to the source side. Thereby, without shifting an exposure position of the gate electrode 15 to the source side, a distance between the drain electrode 19 and the gate electrode 15 can be lengthened. Therefore, it is possible to reduce a capacity Cgd between the gate and the drain, and increase a withstand pressure Vgdo between the gate and the drain. Thereby, not only a high-frequency semiconductor device can be realized, but also a high-gain and high-withstanding pressure semiconductor device can be realized.

### Fourth Embodiment

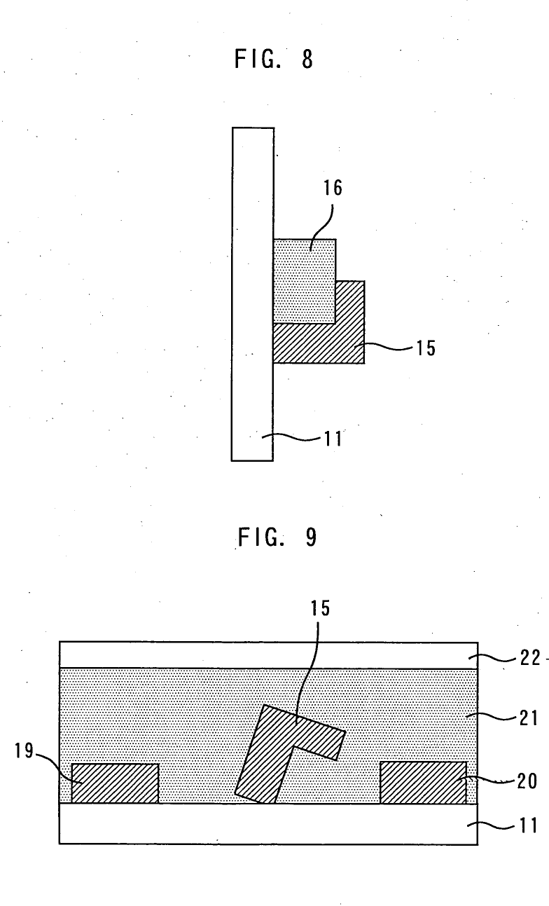

In a fourth embodiment, as shown in FIG. 8, the resist 16 is formed in a state that the semiconductor substrate 11 is tilted so that a side face of the gate electrode 15 which contacts the resist becomes upward. Thereby, it becomes easy to coat with the resist 16 or leave the resist 16 so that the resist 16 contacts the upward side face of the gate electrode 15.

In particular, by turning a recess well of the gate electrode 15 upward, it becomes easy that only the recess well is coated with the resist 16, or the resist 16 remains only in the recess well.

### Fifth Embodiment

In a fifth embodiment, as shown in FIG. 9, the tilted gate electrode 15 is coated with a resist material 21 so that the tilted gate electrode 15 is covered. Then, a passivation film 22 is formed on this resist material 21.

Thereby, bond strength of the tilted gate electrode can be improved. Further, by coating with the resist material, the passivation film can be uniformly formed. Coverage becomes thereby improved, and therefore, damages due to degasification from the outside and moisture are hardly caused, and moisture resistance and reliability can be improved.

Structures of the resist material and the passivation film can be applied to semiconductor devices of ordinary gate electrodes other than the tilted gate electrode.

### Sixth Embodiment

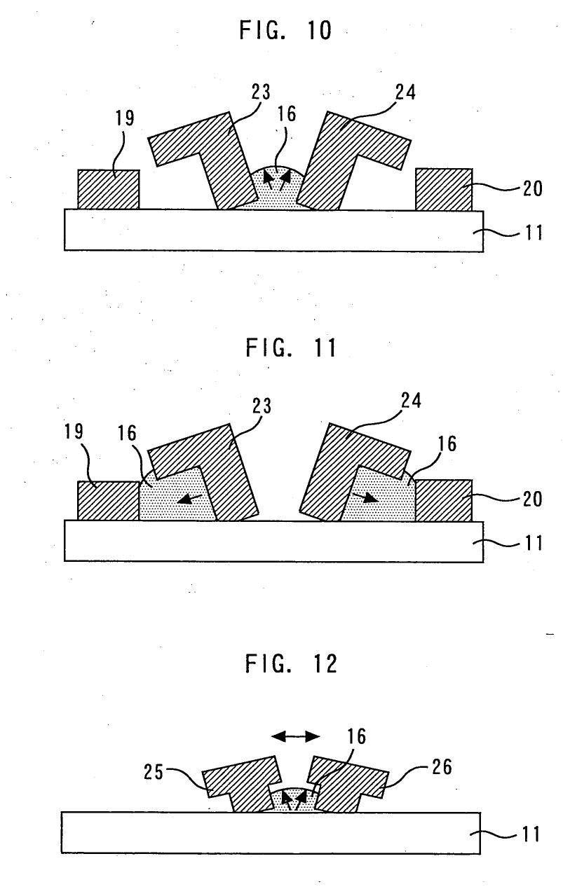

In a sixth embodiment, as shown in FIG. 10, the resist 16 is formed between dual gates 23 and 24. By expanding the resist 16, the dual gates 23 and 24 are tilted outside. Otherwise, as shown in FIG. 11, the resists 16 are respectively formed outside the dual gates 23 and 24. By shrinking the resists 16, the dual gates 23 and 24 are tilted outside.

As described above, also in the case of applying the invention to the dual gate, similar effects can be obtained. Further, by adopting the dual gate, available drain current is increased. Therefore, a high-gain device can be realized.

### Seventh Embodiment

In the foregoing first to sixth embodiments, the gate electrode is tilted by shrinking or expanding the resist. Meanwhile, in the seventh embodiment, as shown in FIG. 12, the resist 16 is provided between two wirings 25 and 26 formed on the semiconductor substrate 11. Thereby, a capacity between the wirings 25 and 26 can be adjusted by shrinkage or expansion of the resist 16. It is possible to form the resist between two resistance lines instead of the two wirings.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2004-183848, filed on Jun. 22, 2004 including specification, claims, drawings and summary, on which the Convention priority of the present application is based, are incorporated herein by reference in its entirety.

1. A method of manufacturing a semiconductor device comprising:
forming a gate electrode on a semiconductor substrate,
forming a resist on the semiconductor substrate so that the resist contacts only one side face of the gate electrode, and
tilting the gate electrode by treating the resist to change its volume.

2. The method of manufacturing a semiconductor device according to claim 1, wherein cross sectional shape of the gate electrode is one of a Γ, a T, and a Y shape.

3. The method of manufacturing a semiconductor device according to claim 1, including tilting the gate electrode to a source side.

4. The method of manufacturing a semiconductor device according to claim 1, including tilting the semiconductor substrate so that the one side face of the gate electrode is upward and then forming the resist on the one side face.

5. The method of manufacturing a semiconductor device according to claim 1, comprising:
coating the tilted gate electrode with a resist material so that the tilted gate electrode is covered with the resist material; and
forming a passivation film on the resist material.

6. The method of manufacturing a semiconductor device according to claim 1 including changing the volume of the resist by shrinking the resist.

7. The method of manufacturing a semiconductor device according to claim 1 including changing the volume of the resist by expanding the resist.
